(19) United States
(12) Patent Application Publication
(10) Pub. No.: US 2024/0415027 A1
(43) Pub. Date: Dec. 12, 2024

(54) FABRICATION SYSTEMS AND METHODS FOR FABRICATING QUANTUM HARDWARE

(71) Applicant: Google LLC, Mountain View, CA (US)

(72) Inventors: Anthony Edward Megrant, Goleta, CA (US); Shiwen Liu, Santa Barbara, CA (US); Brian Burkett, Santa Barbara, CA (US)

(21) Appl. No.: 18/736,749

(22) Filed: Jun. 7, 2024

Related U.S. Application Data
(60) Provisional application No. 63/507,130, filed on Jun. 9, 2023.

(51) Int. Cl. H10N 60/01; B82Y 10/00; B82Y 40/00; G06N 10/40; H10N 60/12; H10N 60/80

(52) U.S. Cl. CPC H10N 60/0912; B82Y 10/00; B82Y 40/00; G06N 10/40; H10N 60/12; H10N 60/805

(57) ABSTRACT

Systems and methods for fabricating quantum hardware for use in a quantum computing system are provided. In one example, the system includes at least one metrology chamber operable to receive a workpiece. The workpiece includes a quantum structure associated with the quantum hardware. The metrology chamber includes at least one detector operable to characterize an atomic scale parameter associated with a surface of the quantum structure. The system includes at least one process chamber operable to receive the workpiece. The at least one process chamber is operable to perform a fabrication process on the quantum structure based at least in part on the atomic scale parameter. The system includes a transfer apparatus operable to transfer the workpiece between the at least one metrology chamber and the at least one process chamber without exposure to ambient.

### CROSS-REFERENCE TO RELATED APPLICATIONS

The present application is based upon and claims the right of priority to U.S. Provisional Patent Application No. 63/507,130, filed on Jun. 9, 2023, the disclosure of which is hereby incorporated by reference herein in its entirety for all purposes.

### FIELD

The present disclosure relates generally to quantum computing systems.

### BACKGROUND

Quantum computing is a computing method that takes advantage of quantum effects, such as superposition of basis states and entanglement to perform certain computations more efficiently than a classical digital computer. In contrast to a digital computer, which stores and manipulates information in the form of bits, e.g., a “1” or “0,” quantum computing systems can manipulate information using quantum bits (“qubits”). A qubit can refer to a quantum device that enables the superposition of multiple states, e.g., data in both the “0” and “1” state, and/or to the superposition of data, itself, in the multiple states. In accordance with conventional terminology, the superposition of a “0” and “1” state in a quantum system may be represented, e.g., as α|0>+β|1> The “0” and “1” states of a digital computer are analogous to respectively of a qubit.

### SUMMARY

Aspects and advantages of embodiments of the present disclosure will be set forth in part in the following description, or can be learned from the description, or can be learned through practice of the embodiments.

One example aspect of the present disclosure is directed to a system fabricating quantum hardware for use in a quantum computing system are provided. In one example, the system includes at least one metrology chamber operable to receive a workpiece. The workpiece includes a quantum structure associated with the quantum hardware. The metrology chamber includes at least one detector operable to characterize an atomic scale parameter associated with a surface of the quantum structure. The system includes at least one process chamber operable to receive the workpiece. The at least one process chamber is operable to perform a fabrication process on the quantum structure based at least in part on the atomic scale parameter. The system includes a transfer apparatus operable to transfer the workpiece between the at least one metrology chamber and the at least one process chamber without exposure to ambient.

Other aspects of the present disclosure are directed to various systems, methods, apparatuses, non-transitory computer-readable media, computer-readable instructions, and quantum computing devices.

These and other features, aspects, and advantages of various embodiments of the present disclosure will become better understood with reference to the following description and appended claims. The accompanying drawings, which are incorporated in and constitute a part of this specification, illustrate example embodiments of the present disclosure and, together with the description, explain the related principles.

### BRIEF DESCRIPTION OF THE DRAWINGS

Detailed discussion of embodiments directed to one of ordinary skill in the art is set forth in the specification, which refers to the appended figures, in which:

FIG. 1 depicts an example embodiment of a quantum computing system according to example aspects of the present disclosure.

FIG. 2 depicts an example system for fabricating quantum hardware according to example embodiments of the present disclosure;

FIG. 3 depicts a flow chart of an example method according to example embodiments of the present disclosure;

FIG. 4 depicts an example system for fabricating quantum hardware according to example embodiments of the present disclosure;

FIG. 5 depicts a flow chart of an example method according to example embodiments of the present disclosure;

FIG. 6 depicts an example system for fabricating quantum hardware according to example embodiments of the present disclosure;

FIG. 7 depicts an example system for fabricating quantum hardware according to example embodiments of the present disclosure;

### DETAILED DESCRIPTION

Example aspects of the present disclosure are directed to quantum computing systems, and more particularly to systems and methods to be used in the fabrication of quantum hardware (e.g., a quantum processor comprising one or more qubits in a quantum computing system). One of the commonly used circuits for quantum computing systems includes a quantum structure such as a nonlinear quantum oscillator (e.g., acting as a qubit) coupled to a quantum harmonic oscillator (e.g., acting as a resonator). The circuit provides for quantum non-demolition measurements of the qubit state through circuit quantum electrodynamics (QED).

A process flow for fabricating quantum hardware including one or more qubits on a chip may include one or more process steps including, for instance, lithographic patterning, thin film deposition, and other process steps for fabrication of planar devices on silicon or sapphire substrates. One example quantum structure used in the fabrication of qubits is the superconducting Josephson junction. Fabrication of Josephson junctions (e.g., Al-AlOx-Al Josephson junctions) is an example of quantum structure fabrication using these process flows.

In quantum hardware fabrication, quantum structures such as superconducting Josephson junctions (nano-scaled structures) and their adjacent or linked elements may be built on atomic level clean surfaces and interfaces on substrates. However, due to the nature of the fabrication process flows, there may be contamination, defects, or damage left on the surfaces and interfaces. Those materials imperfections in planar superconducting quantum circuits may be the sources of two-level-system (TLS) defects which contribute significantly to decoherence, ultimately limiting the performance of quantum computation in quantum computing systems.

Aspects of the present disclosure are directed to systems and methods for quantum hardware fabrication that reduce the likelihood of errors in quantum computing systems associated with imperfections in quantum structures. The systems and methods according to example aspects of the present disclosure may provide for an integrated quantum hardware fabrication system that may combine surface treatment, film deposition, and surface characterization techniques without exposure to ambient (e.g., via ultra-high vacuum environment) to reduce the likelihood of contamination after conducting the surface treatment process and/or the surface characterization. As used herein, “ambient” refers to conditions outside of the workpiece fabrication system and/or conditions similar to those outside of the workpiece fabrication system, such as conditions at atmospheric pressure, room temperature, and/or exposure to air.

For instance, some example embodiments of the present disclosure may include a fabrication system that can provide for surface treatment (e.g., a plasma-based cleaning process, ion beam based-cleaning process, etc.) on a surface of a workpiece for fabrication of one or more quantum structures. The system may include one or more detectors capable of characterizing an atomic scale parameter of the surface with a high detection limit (e.g., 1×10¹⁴ atoms/cm³ or greater) without having to expose the workpiece to ambient conditions. Subsequent to surface characterization, the workpiece may be transferred without exposure to ambient (e.g., under vacuum) to a process chamber (e.g., a deposition chamber) for subsequent process steps (e.g., deposition) on the surface to form at least a portion of the quantum structure.

As used herein, an atomic scale parameter refers to a measurement or metric that provides information about the properties or features of a surface of the workpiece or quantum structure at an atomic level. The atomic scale parameter may be used to evaluate the quality, smoothness, roughness, composition, presence of contaminants, or other attributes of the surface. Example atomic scale parameters may be associated with surface composition, surface topography, surface energy, surface defects, surface charge, or other parameters.

In some examples, a fabrication system may include one or more metrology chambers and one or more process chambers. The metrology chamber(s) may be configured to perform characterization of an atomic scale parameter of a surface of a quantum structure on a workpiece. The process chamber(s) may be operable to conduct one or more portions of a fabrication process for the quantum structure, such as a surface treatment process, a thermal process (e.g., heating process, annealing process, etc.), or a deposition process (e.g., chemical vapor deposition, physical vapor deposition, etc.). The workpiece may be transferred from the metrology chamber to the process chamber after conducting a surface characterization of the quantum structure using a transfer apparatus without exposure of the workpiece to ambient. For instance, the workpiece may be transferred by a workpiece handling robot in a vacuum transfer chamber that is maintained at vacuum during the transfer of the workpiece. In this way, the workpiece is not exposed to contaminants after performing the materials characterization. The subsequent fabrication process in the process chamber may be performed based on more accurate materials characterization of the workpiece.

In some examples, a fabrication process may be performed in the metrology chamber. For instance, in some examples, the metrology chamber may also be a surface treatment chamber for conducting a surface treatment process on the workpiece. The metrology chamber may include an in-situ detector to characterize an atomic scale parameter associated with the surface associated with formation of a quantum structure on the workpiece. As used herein, an “in-situ” detector refers to a detector capable of performing a surface characterization in the same chamber in which a fabrication process is performed, such as a surface treatment process or a thermal treatment process.

As used herein, a surface treatment process refers to a process conducted on a surface of the workpiece on which at least a portion of a quantum structure (e.g., a superconducting qubit, such as a superconducting Josephson junction) is formed. A surface treatment process may include a cleaning process, such as an atomic level cleaning process. The surface treatment process may include an etching process, an oxidation process, a surface passivation process, a surface modification process, or other surface treatment process. The surface treatment process may be a plasma-based cleaning process, ion beam-based cleaning process, or other suitable cleaning process.

A thermal process refers to a process where a workpiece is exposed to heating, such as a rapid thermal heating process, a bake process, an annealing process, or other suitable process. In some examples, a thermal process may be operable to increase a temperature of a workpiece to at least about 200° C., such as at least about 400° C. In some examples, a thermal process may be operable to increase the temperature of a workpiece to a very high temperature, such as at least about 800° C., such as at least about 1000° C.

A deposition process refers to a process by which a material or layer is deposited on a surface of the workpiece. A deposition process may be a chemical vapor deposition (CVD) process, a physical vapor deposition process (PVD), a sputtering process, an epitaxial growth process, an E-beam evaporation process, an atomic layer deposition (ALD) process, or other suitable process where a material is formed or deposited on a surface.

One example implementation of the present disclosure is directed to a system for fabrication of a quantum structure on a surface of a workpiece. The quantum structure may be, for instance, a superconducting Josephson junction to be used as part of a qubit for a quantum processor.

The fabrication system may include an outgas chamber. An outgas chamber may be used to remove contaminants from the workpiece prior to being introduced, for instance, into one of the metrology chamber(s) or one of the process chamber(s) of the fabrication system. In some embodiments, the outgas chamber may include a detector used to monitor, for instance, volatile compounds associated with the workpiece (e.g., volatile organic compounds). The detector may be, for instance, a mass spectrometer associated with a residual-gas-analyzer (RGA). The outgas chamber may be considered a metrology chamber for the fabrication system.

The fabrication system may include a surface treatment chamber. The surface treatment chamber may be configured to perform a surface treatment process on the workpiece. The surface treatment chamber may or may not include an in-situ detector, such as an ellipsometer, an optical emission spectroscopy (OES) detector, or a residual gas analyzer (RGA) detector. In examples wherein the surface treatment chamber includes an in-situ detector, the surface treatment chamber may be considered both a metrology chamber and a process chamber for the fabrication system.

The fabrication system may include a materials characterization chamber. A materials characterization chamber may include a detector operable to detect an atomic scale parameter associated with a surface of the workpiece (e.g., a surface or interface on which at least portion of a quantum structure is formed) at a high detection limit, such as at least about 1×10¹⁴ atoms/cm³. In some examples, the materials characterization chamber may include, for instance, a mass spectrometer configured to provide secondary-ion-mass-spectroscopy (D-SIMS) and/or time-of-flight-mass-spectroscopy (TOF-SIMS). In some examples, the materials characterization chamber may include a detector associated with, for instance, X-ray Photoelectron Spectroscopy (XPS), scanning tunneling microscope (STM), micro/nano spot infrared spectroscopy (or atomic force microscope infrared spectroscopy), and Auger electron spectroscopy (AES).

The fabrication system may include a thermal processing chamber. The thermal processing chamber may be configured to perform a thermal process on the workpiece. In this regard, the thermal processing chamber may be considered a process chamber for the fabrication system. In some examples, the thermal processing chamber may be a thermal desorption spectroscopy (TDS) chamber having a detector operable to perform TDS measurements. The TDS measurements may measure or characterize (e.g., using a mass spectrometer) the desorption of species as a function of temperature on a surface of the workpiece.

The fabrication system may include a deposition chamber. The deposition chamber may be operable to perform a deposition process on the workpiece, for instance, to form the quantum structure, such as a qubit. In some embodiments, the deposition chamber may be used to deposit a layer or film on the workpiece after the workpiece has been subjected to a surface treatment process and/or a materials characterization process. The system may include other process chambers (e.g., etch chambers) without deviating from the scope of the present disclosure.

According to example embodiments of the present disclosure, the fabrication system may include a transfer apparatus (e.g., transfer chamber with one or more workpiece handling robots or other transfer systems) that is coupled to one or more of the outgas chamber, the surface treatment chamber, the thermal process chamber, the materials characterization chamber and/or the deposition chamber. The transfer apparatus may be operable to transfer the workpiece among the chambers without exposure to ambient under vacuum conditions. For instance, the transfer apparatus may be configured to operate at high vacuum (e.g., 1×10⁻⁷ torr) or ultra-high vacuum (e.g., 1×10⁻⁹ torr).

Aspects of the present disclosure provide a number of technical effects and benefits. For instance, quantum structures such as superconducting Josephson junctions (nano-scaled structures) and their adjacent or linked elements may be components of quantum hardware which are built on atomic level. The quantum structures may be built upon and/or may include clean surfaces and interfaces. Combining surface treatment with monitoring, thin film deposition, and advanced surface analysis in a fabrication system with vacuum capability may allow fabrication of quantum structures on surfaces and interfaces free from contamination for reducing two-level-system (TLS) defects. This will lead to improved quantum hardware quality with high coherence performance. Moreover, the fabrication systems and methods according to example aspects of the present disclosure may reduce the cycle time from fabrication process to surface materials characterization and vice versa. In this way, manufacturing throughput of quality quantum hardware may be increased.

With reference now to the FIGS., example embodiments of the present disclosure will be discussed in further detail. As used here, the use of the term “about” in conjunction with a value refers to within 20% of the value.

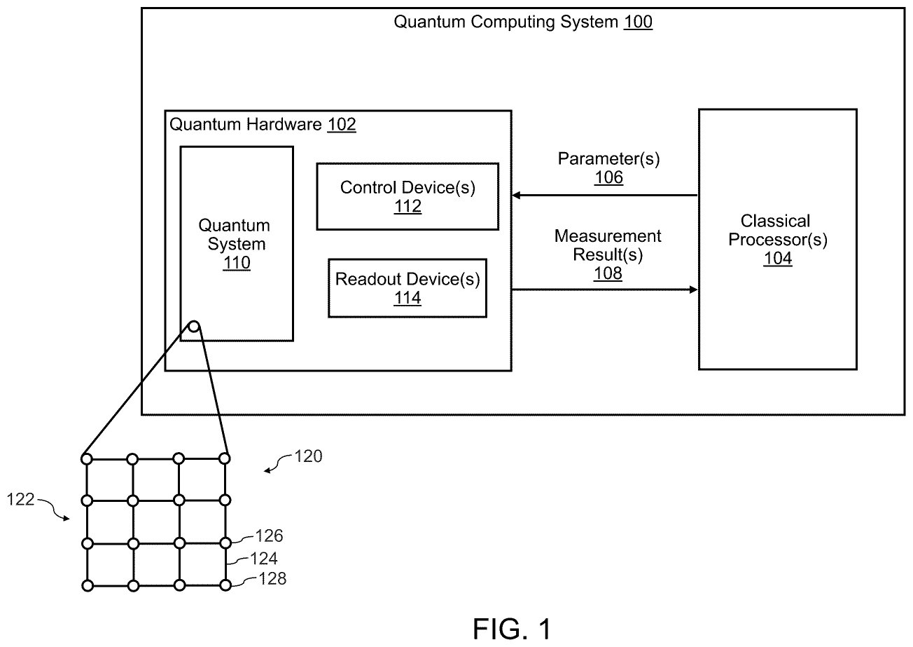

FIG. 1 depicts an example quantum computing system 100. The system 100 is an example of a system of one or more classical computers and/or quantum computing devices in one or more locations, in which the systems, components, and techniques described below may be implemented. Those of ordinary skill in the art, using the disclosures provided herein, will understand that other quantum computing devices or systems may be used without deviating from the scope of the present disclosure.

The system 100 includes quantum hardware 102 in data communication with one or more classical processors 104. The classical processors 104 may be configured to execute computer-readable instructions stored in one or more memory devices to perform operations, such as any of the operations described herein. The quantum hardware 102 includes components for performing quantum computation. For example, the quantum hardware 102 includes a quantum system 110, control device(s) 112, and readout device(s) 114 (e.g., readout resonator(s)). The quantum system 110 may include one or more multi-level quantum subsystems, such as a register of qubits (e.g., qubits 120). In some implementations, the multi-level quantum subsystems may include superconducting qubits, such as flux qubits, charge qubits, transmon qubits, gmon qubits, etc.

The type of multi-level quantum subsystems that the system 100 utilizes may vary. For example, in some cases it may be convenient to include one or more readout device(s) 114 attached to one or more superconducting qubits, e.g., transmon, flux, gmon, xmon, or other qubits. In other cases, ion traps, photonic devices or superconducting cavities (e.g., with which states may be prepared without requiring qubits) may be used. Further examples of realizations of multi-level quantum subsystems include fluxmon qubits, silicon quantum dots or phosphorus impurity qubits.

Quantum circuits may be constructed and applied to the register of qubits included in the quantum system 110 via multiple control lines that are coupled to one or more control devices 112. Example control devices 112 that operate on the register of qubits may be used to implement quantum gates or quantum circuits having a plurality of quantum gates, e.g., Pauli gates, Hadamard gates, controlled-NOT (CNOT) gates, controlled-phase gates, T gates, multi-qubit quantum gates, coupler quantum gates, etc. The one or more control devices 112 may be configured to operate on the quantum system 110 through one or more respective control parameters (e.g., one or more physical control parameters). For example, in some implementations, the multi-level quantum subsystems may be superconducting qubits and the control devices 112 may be configured to provide control pulses to control lines to generate magnetic fields to adjust the frequency of the qubits.

The quantum hardware 102 may further include readout devices 114 (e.g., readout resonators). Measurement results 108 obtained via measurement devices may be provided to the classical processors 104 for processing and analyzing. In some implementations, the quantum hardware 102 may include a quantum circuit and the control device(s) 112 and readout devices(s) 114 may implement one or more quantum logic gates that operate on the quantum system 102 through physical control parameters (e.g., microwave pulses) that are sent through wires included in the quantum hardware 102. Further examples of control devices include arbitrary waveform generators, wherein a DAC (digital to analog converter) creates the signal.

The readout device(s) 114 may be configured to perform quantum measurements on the quantum system 110 and send measurement results 108 to the classical processors 104. In addition, the quantum hardware 102 may be configured to receive data specifying physical control qubit parameter values 106 from the classical processors 104. The quantum hardware 102 may use the received physical control qubit parameter values 106 to update the action of the control device(s) 112 and readout devices(s) 114 on the quantum system 110. For example, the quantum hardware 102 may receive data specifying new values representing voltage strengths of one or more DACs included in the control devices 112 and may update the action of the DACs on the quantum system 110 accordingly. The classical processors 104 may be configured to initialize the quantum system 110 in an initial quantum state, e.g., by sending data to the quantum hardware 102 specifying an initial set of parameters 106.

In some implementations, the readout device(s) 114 may take advantage of a difference in the impedance for the |0> and |1> states of an element of the quantum system, such as a qubit, to measure the state of the element (e.g., the qubit). For example, the resonance frequency of a readout resonator may take on different values when a qubit is in the state |0> or the state |1>, due to the nonlinearity of the qubit. Therefore, a microwave pulse reflected from the readout device 114 carries an amplitude and phase shift that depend on the qubit state. In some implementations, a Purcell filter may be used in conjunction with the readout device(s) 114 to impede microwave propagation at the qubit frequency.

In some embodiments, the quantum system 110 may include a plurality of qubits 120 arranged, for instance, in a two-dimensional grid 122. For clarity, the two-dimensional grid 122 depicted in FIG. 1 includes 4×4 qubits, however in some implementations the system 110 may include a smaller or a larger number of qubits. In some embodiments, the multiple qubits 120 may interact with each other through multiple qubit couplers, e.g., qubit coupler 124. The qubit couplers may define nearest neighbor interactions between the multiple qubits 120. In some implementations, the strengths of the multiple qubit couplers are tunable parameters. In some cases, the multiple qubit couplers included in the quantum computing system 100 may be couplers with a fixed coupling strength.

In some implementations, the multiple qubits 120 may include data qubits, such as qubit 126 and measurement qubits, such as qubit 128. A data qubit is a qubit that participates in a computation being performed by the system 100. A measurement qubit is a qubit that may be used to determine an outcome of a computation performed by the data qubit. That is, during a computation an unknown state of the data qubit is transferred to the measurement qubit using a suitable physical operation and measured via a suitable measurement operation performed on the measurement qubit.

In some implementations, each qubit in the multiple qubits 120 may be operated using respective operating frequencies, such as an idling frequency and/or an interaction frequency(s) and/or readout frequency and/or reset frequency. The operating frequencies may vary from qubit to qubit. For instance, each qubit may idle at a different operating frequency. The operating frequencies for the qubits 120 may be chosen before a computation is performed.

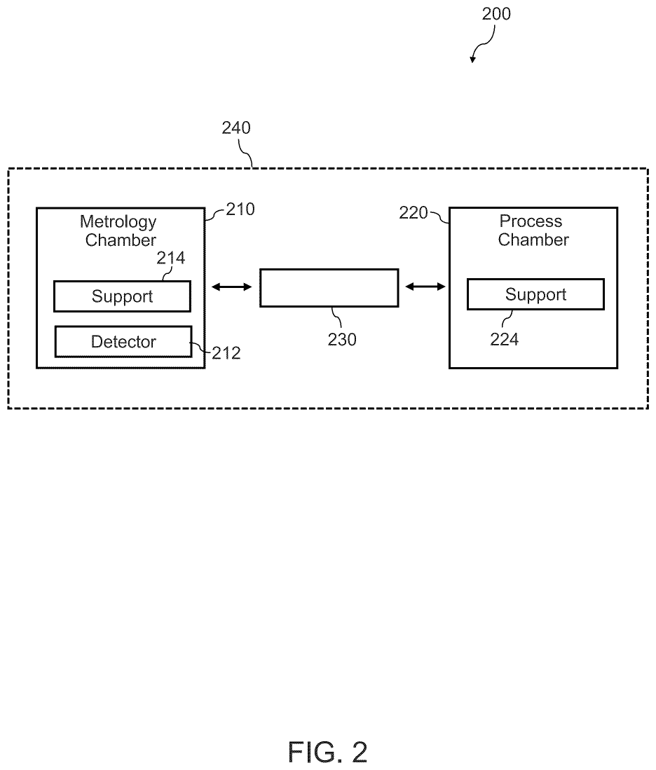

FIG. 2 depicts an example system 200 for fabricating quantum hardware for use in a quantum computing system according to example embodiments of the present disclosure. The system 200 may be used to process a workpiece having one or more surfaces associated with a quantum structure, such as a qubit. The workpiece may be, for instance, a wafer having a substrate (e.g., silicon, sapphire, etc,) with or more surfaces for formation of a quantum structure, such as a superconducting Josephson junction. The wafer may be processed to form one or more quantum structures that will form a part (e.g., one or more qubits) of quantum hardware for a quantum computing system.

The system 200 may include a metrology chamber 210. The system 200 may include a process chamber 220. The system 200 may include a transfer apparatus 230. The transfer apparatus 230 may be in process flow communication with the metrology chamber 210 and the process chamber 220. The transfer apparatus 230 may be operable to transfer a workpiece having one or more quantum structures (or surfaces for quantum structure fabrication) between the metrology chamber 210 and the process chamber 220 without exposure of the workpiece to ambient.

For instance, the transfer apparatus 230 may include a chamber operable in a vacuum environment 240 (e.g., a vacuum chamber). For instance, the transfer apparatus 230 may be operable in high vacuum and/or ultra high vacuum conditions. In some examples, during transfer of a workpiece in and/or out of the metrology chamber 210, the metrology chamber 210 may be operable in the vacuum environment 240 under high vacuum or ultra-high vacuum conditions. Similarly, during transfer of a workpiece in and/or out of the process chamber 220, the process chamber 220 may be operable in the vacuum environment 240 in high vacuum or ultra-high vacuum conditions. The system 200 may include one or more components to facilitate maintaining the vacuum environment 240. For instance, the system 200 may include one or more load lock chambers, vacuum pumps, gate valves, doors between chambers and the transfer apparatus 230 to facilitate maintaining the vacuum environment 240.

The transfer apparatus 230 may include a workpiece handling robot. The workpiece handling robot may include one or more robotic arms and workpiece handling apparatus (e.g., end effectors) for moving and transferring workpieces within the system 200. The workpiece handling apparatus may include or be in communication with workpiece positioning systems to ensure proper placement of a workpiece in the metrology chamber 210 and/or the process chamber 220.

The metrology chamber 210 may include at least one detector 212. The at least one detector 212 may be operable to perform surface characterization of a surface of the workpiece on which a quantum structure and/or a portion of a quantum structure is to be formed. The at least one detector 212 may be operable to detect or characterize an atomic scale parameter associated with the surface.

One example detector 212 may include a mass spectrometer. A mass spectrometer may be used to identify and quantify the chemical composition of the surface of the workpiece. A mass spectrometer may operate by ionizing the surface and separating the resulting ions based on their mass-to-charge ratio. The separated ions may be detected, providing information about the composition of the surface.

In some examples, the mass spectrometer may be a residual gas analyzer (RGA) detector. The RGA detector may be used to measure the composition of a gas in a vacuum system. The RGA detector may be a part of a metrology chamber 210 that is serving as an outgas chamber and/or is serving as an in-situ detector that forms part of a process chamber, such as a surface treatment chamber. In this example, the surface treatment chamber may be both a metrology chamber and a process chamber.

In some examples, the mass spectrometer may be a secondary-ion-mass-spectroscopy (SIMS) detector. A SIMS detector may be used to characterize the elemental and isotopic composition of a surface of the workpiece. A SIMS detector may operate by bombarding the surface of a sample with a primary ion beam, typically composed of positive ions. The impact of the primary ions may cause the ejection of secondary ions from the surface, which are then analyzed based on their mass-to-charge ratios.

In some examples, the at least one detector 212 may be an X-ray photoelectron spectroscopy (XPS) detector. An XPS detector may analyze the surface of the workpiece by bombarding the surface with X-rays, causing the emission of photoelectrons from the surface, The kinetic energy and intensity of the emitted photoelectrons may provide information about the composition of the surface, chemical bonding, oxidation states, and surface contamination.

In some examples, the at least one detector 212 may be a thermal desorption spectroscopy (TDS) detector. The TDS detector 212 may measure desorbed species from the surface of the workpiece during a temperature ramp (e.g., up to about 1000° C. or greater).

The metrology chamber 210 may include a workpiece support 214 (e.g., a pedestal or electrostatic chuck) used to support, hold, or clamp the workpiece during surface characterization by the at least one detector. The metrology chamber 210 may include other components useful for surface characterization of the workpiece, such as a workpiece positioning system, heating system (e.g., radiant heat source, resistive heat source, inductive heat source, plasma heat source, laser heat source), vacuum pump to operate the metrology chamber 210 in high vacuum or ultra-high vacuum conditions, a gate valve, a door to close of the metrology chamber 210 from the transfer apparatus 230 or rest of the system 200, etc.

The metrology chamber 210 may serve as a process chamber for system 200. For instance, in some examples, the metrology chamber 210 may be a surface treatment chamber with an in-situ detector 212. In some examples, the metrology chamber 210 may be a thermal process chamber with a TDS detector.

The process chamber 220 may be used to perform a fabrication process on the workpiece. The fabrication process may be a deposition process, a surface treatment process, a thermal process, or other suitable process used to form a quantum structure, such as a superconducting Jospheson junction on the workpiece. The process chamber 220 may include a workpiece support 224 (e.g., a pedestal or electrostatic chuck) used to support, hold, or clamp the workpiece during surface characterization by the at least one detector. The process chamber 220 may include components suitable for performing a fabrication process, such as a plasma source, a gas flow inlet, a workpiece positioning system, heating system, vacuum pump to operate the process chamber 220 in high vacuum or ultra-high vacuum conditions, a gate valve, a door to isolate the process chamber 220 from the transfer apparatus 230 or rest of the system 200.

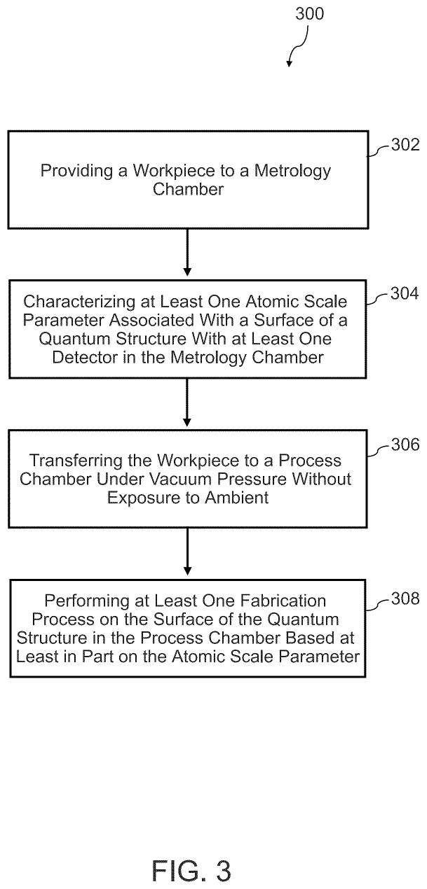

FIG. 3 depicts a flow diagram of one example method 300 for fabricating quantum hardware for use in a quantum computing system according to example embodiments of the present disclosure. The method 300 may be implemented using the system 200 described with reference to FIG. 2. The method 300 may be implemented with other systems without deviating from the scope of the present disclosure. FIG. 3 depicts steps performed in a particular order for purposes of illustration and discussion. Those of ordinary skill in the art, using the disclosures provided herein, will understand that the process steps or operations of any of the methods described herein may be expanded, include steps not illustrated, omitted, rearranged, and/or modified in various ways without deviating from the scope of the present disclosure.

At 302, the method may include providing a workpiece to a metrology chamber. The workpiece may include one or more surfaces associated with a quantum structure, such as a superconducting Josephson junction. For instance, the method may include transferring a workpiece into the metrology chamber 210 and placing the workpiece on a workpiece support 214.

At 304, the method may include characterizing at least one atomic scale parameter associated with a surface of the quantum structure with at least one detector in the metrology chamber. For instance, the method may include characterizing at least one atomic scale parameter of the workpiece with the at least one detector 212. The atomic scale parameter may be associated with a detection limit of at least about 1×10¹⁴ atoms/cm³. As discussed above, the at least one detector may be a mass spectrometer or other suitable detector. In some examples, the at least one detector is an in-situ detector that is part of, for instance, a surface treatment chamber or other chamber.

At 306, after characterizing the at least one atomic scale parameter, the method may include transferring the workpiece to a process chamber under vacuum pressure without exposure to ambient. For instance, the transfer apparatus 230 may transfer the workpiece from the metrology chamber 210 to the process chamber 220 without exposing the workpiece to the ambient environment and while maintaining the workpiece in high vacuum or ultra-high vacuum conditions.

At 308, the method may include performing at least one fabrication process on the surface of the quantum structure in the process chamber based at least in part on the atomic scale parameter. For instance, if the atomic scale parameter indicates that the surface is suitable for further fabrication steps (e.g., there is no surface contamination and/or surface defects), the method may include performing the fabrication process on the workpiece. An example fabrication process may be a deposition process, thermal process, or surface treatment process.

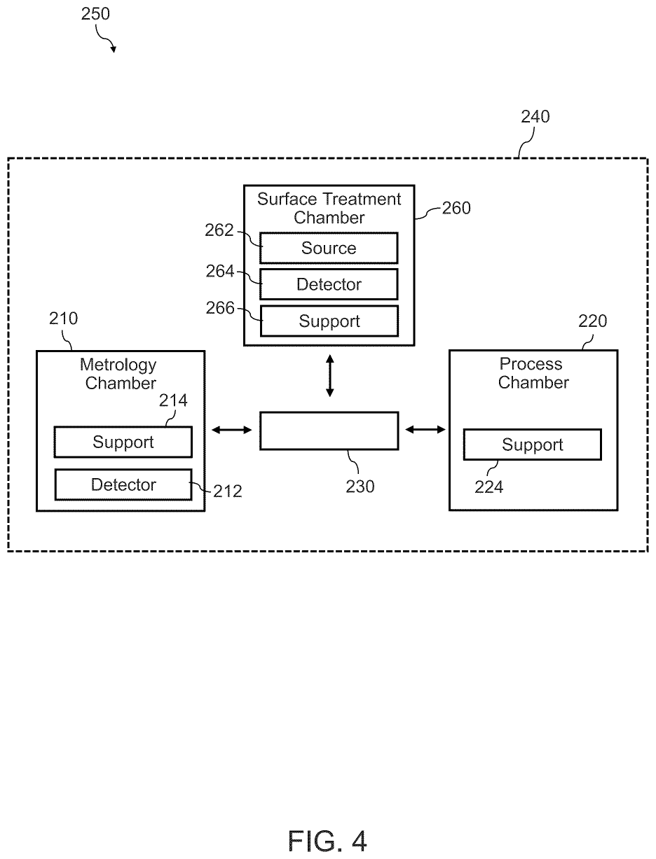

FIG. 4 depicts another example system 250 for fabricating quantum hardware for use in a quantum computing system according to example embodiments of the present disclosure. The system is similar to that of FIG. 2, except that the system 250 includes an additional surface treatment chamber 260.

The surface treatment chamber 260 may be used to perform a surface treatment process on the surface of the workpiece (e.g., a cleaning process, an etching process, an oxidation process, a surface passivation process, a surface modification process, or other surface treatment process). The surface treatment process may be an atomic level surface treatment process. The surface treatment chamber 260 may include, for instance, a treatment source 262. The treatment source 262 may be a plasma source (e.g., inductively coupled plasma source, capacitively coupled plasma source, or other plasma source) used to generate a plasma for surface treatment of the surface of the workpiece. The treatment source 262 may include an ion beam source. The surface treatment chamber 260 may include other suitable treatment sources 262 without deviating from the scope of the present disclosure.

The surface treatment chamber 260 may include, in some embodiments, an in situ detector 264. The in-situ detector 264 may be, for instance, an ellipsometer, an optical emission spectroscopy (OES) detector, a RGA detector, or other suitable detector. In some embodiments, the in-situ detector 264 may be any of the detectors described herein, such as any of the detectors 212 described with reference to the metrology chamber 210.

The surface treatment chamber 260 may include a workpiece support 266 (e.g., a pedestal or electrostatic chuck) used to support, hold, or clamp the workpiece during surface treatment. The surface treatment chamber 260 may include other components useful for surface treatment of the workpiece, such as a workpiece positioning system, heating system, vacuum pump to operate the surface treatment chamber 260 in high vacuum or ultra-high vacuum conditions, a gate valve, a door to isolate the surface treatment chamber 260 from the transfer apparatus 230 or rest of the system 200, etc.

The transfer apparatus 230 may be operable to transfer a workpiece between the surface treatment chamber 260 and either the metrology chamber 210 or the process chamber 220 without exposure to ambient. For instance, the transfer apparatus 230 may transfer the workpiece without exposure to ambient under vacuum (e.g., high vacuum or ultra-high vacuum) conditions.

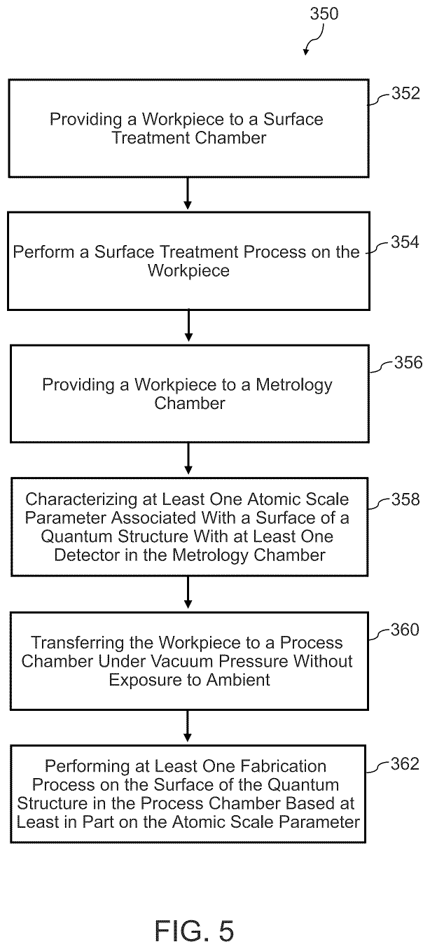

FIG. 5 depicts a flow diagram of one example method 350 for fabricating quantum hardware for use in a quantum computing system according to example embodiments of the present disclosure. The method 350 may be implemented using the system 250 described with reference to FIG. 4. The method 350 may be implemented with other systems without deviating from the scope of the present disclosure. FIG. 5 depicts steps performed in a particular order for purposes of illustration and discussion. Those of ordinary skill in the art, using the disclosures provided herein, will understand that the process steps or operations of any of the methods described herein may be expanded, include steps not illustrated, omitted, rearranged, and/or modified in various ways without deviating from the scope of the present disclosure.

At 352, the method may include providing the workpiece to a surface treatment chamber. The workpiece may include one or more surfaces associated with a quantum structure, such as a superconducting Josephson junction. For instance, the method may include transferring a workpiece into the surface treatment chamber 260 of FIG. 4 and placing the workpiece on a workpiece support 266.

At 354, the method may include performing a surface treatment process on the workpiece. For instance, the surface treatment source 262 may be operated to perform a surface treatment process on the workpiece.

At 356, the method may include providing a workpiece to a metrology chamber. For instance, the method may include transferring a workpiece into the metrology chamber 210 and placing the workpiece on a workpiece support 214.

At 358, the method may include characterizing at least one atomic scale parameter associated with a surface of the quantum structure with at least one detector in the metrology chamber. For instance, the method may include characterizing at least one atomic scale parameter of the workpiece with the at least one detector 212. The atomic scale parameter may be associated with a detection limit of at least about 1×10¹⁴ atoms/cm³. As discussed above, the at least one detector may be a mass spectrometer or other suitable detector.

At 360, after characterizing the at least one atomic scale parameter, the method may include transferring the workpiece to a process chamber under vacuum pressure without exposure to ambient. For instance, the transfer apparatus 230 may transfer the workpiece from the metrology chamber 210 to the process chamber 220 without exposing the workpiece to the ambient environment and while maintaining the workpiece in high vacuum or ultra-high vacuum conditions.

At 362, the method may include performing at least one fabrication process on the surface of the quantum structure in the process chamber based at least in part on the atomic scale parameter. For instance, if the atomic scale parameter indicates that the surface is suitable for further fabrication steps (e.g., there is no surface contamination and/or surface defects), the method may include performing the fabrication process on the workpiece. An example fabrication process may be a deposition process, thermal process, or surface treatment process.

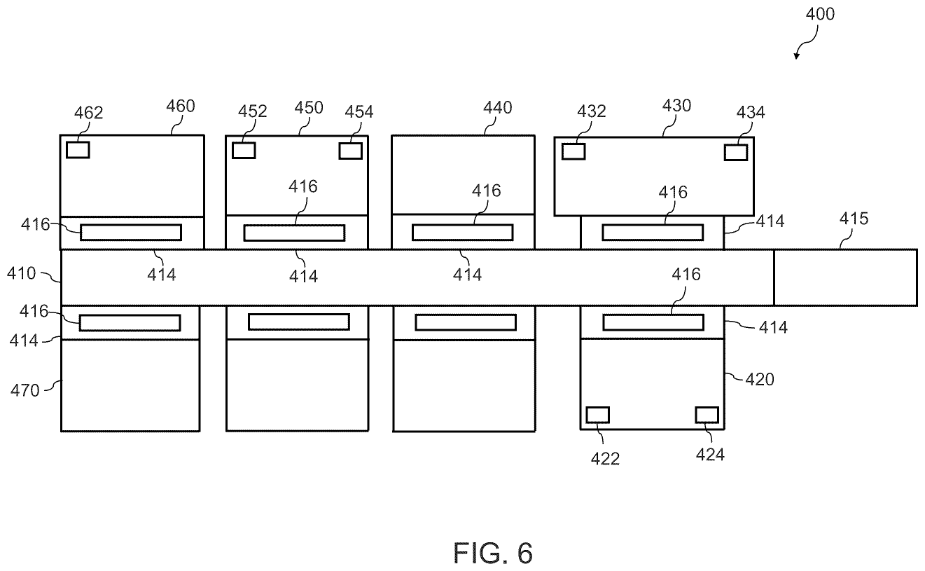

FIG. 6 depicts an example system 400 for fabricating quantum hardware for use in a quantum computing system according to example embodiments of the present disclosure. The system 400 is a linear system including a linear transfer tube 410. The linear transfer tube 410 may be in process flow communication with one or more chambers, such as outgas chamber 420, a surface treatment chamber 430, a deposition chamber 440, a thermal process chamber 450, a materials characterization chamber 460, and/or other process chambers 470.

The linear transfer tube 410 may be operated in high vacuum or ultra-high vacuum conditions. The linear transfer tube may be coupled to a load lock chamber 415. The load lock chamber 415 may facilitate the transfer of a workpiece from ambient (e.g., at atmospheric pressure) environment and the vacuum conditions of the linear transfer tube 410. The load lock chamber 415 may be a sealed chamber with two or more doors. One of the doors may face the ambient environment (e.g., at atmospheric pressure). The other door may face the linear transfer tube 410. A workpiece may be provided into the load lock chamber from the ambient environment. The load lock chamber 415 may then be pumped down to high vacuum or ultra-high vacuum conditions. The workpiece may then be transferred to the linear transfer tube 410 (e.g., using a workpiece handling robot).

The linear transfer tube 410 may include one or more workpiece handling robots. The workpiece handling robot may include one or more robotic arms and workpiece handling apparatus (e.g., end effectors) for moving and transferring workpieces within the system 400. The workpiece handling apparatus may include or be in communication with workpiece positioning systems to ensure proper placement of a workpiece in the various chambers. The workpiece handling robot may be configured to move linearly (e.g., along a rail or other track) in the linear transfer tube 410 to obtain access to the chambers coupled to the linear transfer tube 410.

The linear transfer tube 410 may be coupled to one or more of the outgas chamber 420, a surface treatment chamber 430, a deposition chamber 440, a thermal process chamber 450, a materials characterization chamber 460, and/or other process chambers 470 through a door 414 and a gate valve 416. The door 414 (e.g., a slit door) allows each chamber to be sealed off from the vacuum environment of the linear transfer tube 410. The gate valve 416 allows each chamber to be pumped down to a vacuum environment prior to transfer of a workpiece between the chamber and the linear transfer tube 410.

The outgas chamber 420 may be used to remove contaminants from the workpiece prior to being introduced, for instance, to other chambers in the system 400. The outgas chamber 420 may include a heating system 424 operable to heat the workpiece to a temperature of at least about 200 C°. The heating system 424 may be for instance, a radiant heat source (e.g., lamp), a resistive heat source, an inductive heat source, a plasma heat source, a laser heat source, etc.). In some embodiments, the outgas chamber 420 may include a detector 422 used to monitor, for instance, volatile compounds associated with the workpiece (e.g., volatile organic compounds). The detector 422 may be, for instance, a mass spectrometer associated with a residual-gas-analyzer (RGA) (e.g., an RGA detector). The outgas chamber 420 may be considered a metrology chamber for the fabrication system. The outgas chamber 420 may include a workpiece support (e.g., a pedestal or electrostatic chuck) used to support, hold, or clamp the workpiece during outgassing.

The surface treatment chamber 430 may be used to perform a surface treatment process on the surface of the workpiece (e.g., a cleaning process, an etching process, an oxidation process, a surface passivation process, a surface modification process, or other surface treatment process). The surface treatment process may be an atomic level surface treatment process. The surface treatment chamber 430 may include, for instance, a treatment source 432. The treatment source 432 may be a plasma source (e.g., inductively coupled plasma source, capacitively coupled plasma source, or other plasma source) used to generate a plasma for surface treatment of the surface of the workpiece. The treatment source 432 may include an ion beam source. The surface treatment chamber may include other suitable treatment sources 432 without deviating from the scope of the present disclosure.

The surface treatment chamber 430 may include, in some embodiments, an in situ detector 434. The in-situ detector 434 may be, for instance, an ellipsometer, an optical emission spectroscopy (OES) detector, a RGA detector, or other suitable detector. In some embodiments, the in-situ detector 434 may be any of the detectors described herein, such as any of the detectors 212 described with reference to the metrology chamber 210. The surface treatment chamber 430 may include a workpiece support (e.g., a pedestal or electrostatic chuck) used to support, hold, or clamp the workpiece during surface treatment.

The deposition chamber 440 may be used to perform a deposition process on the workpiece, such as a surface associated with a quantum structure, such as a superconducting Josephson junction. The deposition chamber 440 may include a workpiece support (e.g., a pedestal or electrostatic chuck) used to support, hold, or clamp the workpiece during deposition. The deposition chamber 440 may include components suitable for performing a fabrication process, such as a plasma source, a gas flow inlet, a workpiece positioning system, heating system, vacuum pump, etc.

The thermal process chamber 450 may be operable to perform a thermal process on the workpiece. In some embodiments, the thermal process chamber 450 may include a heat source 452. The heat source 452 may be, for instance, a radiant heat source (e.g., lamp), a resistive heat source, an inductive heat source, a plasma heat source, a laser heat source, etc.). The thermal process chamber 450 may include a detector 454. The detector 454 may be operable to perform TDS measurements. The TDS measurements may measure or characterize (e.g., using a mass spectrometer) the desorption of species as a function of temperature on a surface of the workpiece. The thermal processing chamber 450 may include a workpiece support (e.g., a pedestal or electrostatic chuck) used to support, hold, or clamp the workpiece during thermal processing.

The materials characterization chamber 460 may include a detector 462 operable to detect an atomic scale parameter associated with a surface of the workpiece (e.g., a surface or interface on which at least portion of a quantum structure is formed) at a high detection limit, such as at least about 1×10¹⁴ atoms/cm³. In some examples, the materials characterization chamber 460 may include, for instance, a mass spectrometer configured to provide secondary-ion-mass-spectroscopy (D-SIMS) and/or time-of-flight-mass-spectroscopy (TOF-SIMS). In some examples, the materials characterization chamber 460 may include a detector associated with, for instance, X-ray Photoelectron Spectroscopy (XPS). The material characterization chamber 460 may include a detector associated with a scanning tunneling microscope (STM), micro/nano spot infrared spectroscopy (or atomic force microscope infrared spectroscopy), and/or Auger electron spectroscopy (AES). The materials characterization chamber 460 may include a workpiece support 464 (e.g., a pedestal or electrostatic chuck) used to support, hold, or clamp the workpiece during thermal processing.

The fabrication system 400 may include one or more other chambers 470 without deviating from the scope of the present disclosure. The other chambers may be metrology chambers and/or process chambers. In addition, the material characterization functionality implemented by the material characterization chamber 460 may be implemented across a plurality of different chambers without deviating from the scope of the present disclosure.

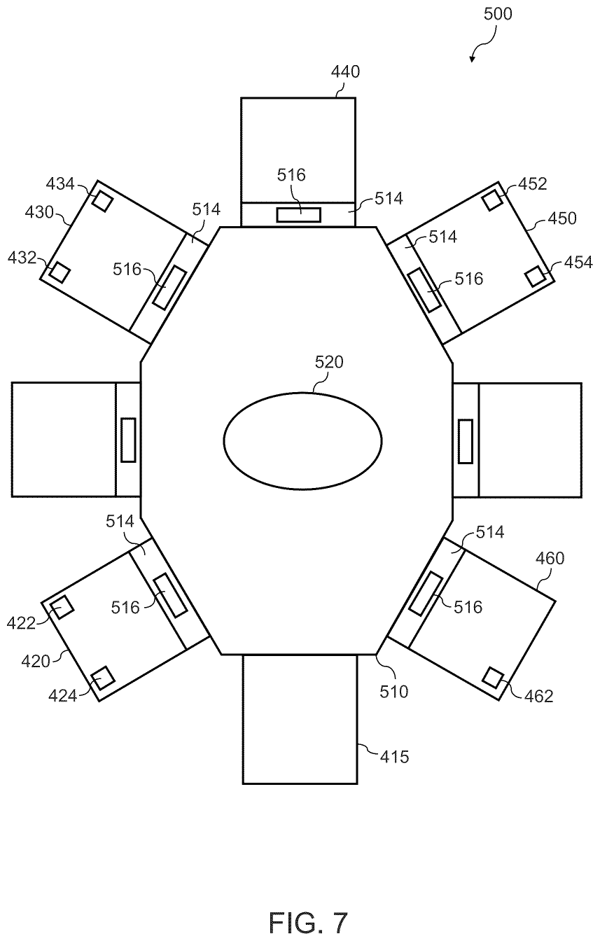

FIG. 7 depicts a fabrication system 500 similar to the fabrication system 400 of FIG. 6, The fabrication system 500 of FIG. 7 is a cluster-based fabrication system 500. More particularly, instead of a linear transfer tube 410 the system 500 includes a cluster vacuum chamber 510. The cluster chamber 510 may be in process flow communication with one or more chambers, such as outgas chamber 420, a surface treatment chamber 430, a deposition chamber 440, a thermal process chamber 450, a materials characterization chamber 460, and/or other process chambers (not illustrated).

The cluster chamber 510 may be operated in high vacuum or ultra-high vacuum conditions. The linear transfer tube may be coupled to a load lock chamber 415. The load lock chamber 415 may facilitate the transfer of a workpiece from ambient (e.g., at atmospheric pressure) environment and the vacuum conditions of the cluster chamber 510. The load lock chamber 415 may be a sealed chamber with two or more doors. One of the doors may face the ambient environment (e.g., at atmospheric pressure). The other door may face the cluster chamber 510. A workpiece may be provided into the load lock chamber from the ambient environment. The load lock chamber 415 may then be pumped down to high vacuum or ultra-high vacuum conditions. The workpiece may then be transferred to the cluster chamber 510 (e.g., using a workpiece handling robot).

The cluster chamber 510 may include one or more workpiece handling robots 520. The workpiece handling robot(s) 520 may include one or more robotic arms and workpiece handling apparatus (e.g., end effectors) for moving and transferring workpieces within the system 500. The workpiece handling robot(s) 520 may include or be in communication with workpiece positioning systems to ensure proper placement of a workpiece in the various chambers. The workpiece handling robot(s) may be a rotary robot.

The cluster chamber 510 may be coupled to one or more of the outgas chamber 420, a surface treatment chamber 430, a deposition chamber 440, a thermal process chamber 450, a materials characterization chamber 460, and/or other process chambers 470 through a door 514 and a gate valve 516. The door 514 (e.g., a slit door) allows each chamber to be sealed off from the vacuum environment of the cluster chamber 510. The gate valve 516 allows each chamber to be pumped down to a vacuum environment prior to transfer of a workpiece between the chamber and the cluster chamber 510.

The fabrication system 500 may include one or more other chambers without deviating from the scope of the present disclosure. The other chambers may be metrology chambers and/or process chambers. In addition, the material characterization functionality implemented by the material characterization chamber 460 may be implemented across a plurality of different chambers without deviating from the scope of the present disclosure.

Implementations of the digital, classical, and/or quantum subject matter and the digital functional operations and quantum operations described in this specification can be implemented in digital electronic circuitry, suitable quantum circuitry or, more generally, quantum computational systems, in tangibly-implemented digital and/or quantum computer software or firmware, in digital and/or quantum computer hardware, including the structures disclosed in this specification and their structural equivalents, or in combinations of one or more of them. The term “quantum computing systems” may include, but is not limited to, quantum computers/computing systems, quantum information processing systems, quantum cryptography systems, or quantum simulators.

Implementations of the digital and/or quantum subject matter described in this specification can be implemented as one or more digital and/or quantum computer programs, i.e., one or more modules of digital and/or quantum computer program instructions encoded on a tangible non-transitory storage medium for execution by, or to control the operation of, data processing apparatus. The digital and/or quantum computer storage medium can be a machine-readable storage device, a machine-readable storage substrate, a random or serial access memory device, one or more qubits/qubit structures, or a combination of one or more of them.

Alternatively or in addition, the program instructions can be encoded on an artificially-generated propagated signal that is capable of encoding digital and/or quantum information (e.g., a machine-generated electrical, optical, or electromagnetic signal) that is generated to encode digital and/or quantum information for transmission to suitable receiver apparatus for execution by a data processing apparatus.

The terms quantum information and quantum data refer to information or data that is carried by, held, or stored in quantum systems, where the smallest non-trivial system is a qubit, i.e., a system that defines the unit of quantum information. It is understood that the term “qubit” encompasses all quantum systems that may be suitably approximated as a two-level system in the corresponding context. Such quantum systems may include multi-level systems, e.g., with two or more levels. By way of example, such systems can include atoms, electrons, photons, ions or superconducting qubits. In many implementations the computational basis states are identified with the ground and first excited states, however it is understood that other setups where the computational states are identified with higher level excited states (e.g., qudits) are possible.

The term “data processing apparatus” refers to digital and/or quantum data processing hardware and encompasses all kinds of apparatus, devices, and machines for processing digital and/or quantum data, including by way of example a programmable digital processor, a programmable quantum processor, a digital computer, a quantum computer, or multiple digital and quantum processors or computers, and combinations thereof. The apparatus can also be, or further include, special purpose logic circuitry, e.g., an FPGA (field programmable gate array), or an ASIC (application-specific integrated circuit), or a quantum simulator, i.e., a quantum data processing apparatus that is designed to simulate or produce information about a specific quantum system. In particular, a quantum simulator is a special purpose quantum computer that does not have the capability to perform universal quantum computation. The apparatus can optionally include, in addition to hardware, code that creates an execution environment for digital and/or quantum computer programs, e.g., code that constitutes processor firmware, a protocol stack, a database management system, an operating system, or a combination of one or more of them.

A digital or classical computer program, which may also be referred to or described as a program, software, a software application, a module, a software module, a script, or code, can be written in any form of programming language, including compiled or interpreted languages, or declarative or procedural languages, and it can be deployed in any form, including as a stand-alone program or as a module, component, subroutine, or other unit suitable for use in a digital computing environment. A quantum computer program, which may also be referred to or described as a program, software, a software application, a module, a software module, a script, or code, can be written in any form of programming language, including compiled or interpreted languages, or declarative or procedural languages, and translated into a suitable quantum programming language, or can be written in a quantum programming language, e.g., QCL, Quipper, Cirq, etc.

A digital and/or quantum computer program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A digital and/or quantum computer program can be deployed to be executed on one digital or one quantum computer or on multiple digital and/or quantum computers that are located at one site or distributed across multiple sites and interconnected by a digital and/or quantum data communication network. A quantum data communication network is understood to be a network that may transmit quantum data using quantum systems, e.g. qubits. Generally, a digital data communication network cannot transmit quantum data, however a quantum data communication network may transmit both quantum data and digital data.

The processes and logic flows described in this specification can be performed by one or more programmable digital and/or quantum computers, operating with one or more digital and/or quantum processors, as appropriate, executing one or more digital and/or quantum computer programs to perform functions by operating on input digital and quantum data and generating output. The processes and logic flows can also be performed by, and apparatus can also be implemented as, special purpose logic circuitry, e.g., an FPGA or an ASIC, or a quantum simulator, or by a combination of special purpose logic circuitry or quantum simulators and one or more programmed digital and/or quantum computers.

For a system of one or more digital and/or quantum computers or processors to be “configured to” or “operable to” perform particular operations or actions means that the system has installed on it software, firmware, hardware, or a combination of them that in operation cause the system to perform the operations or actions. For one or more digital and/or quantum computer programs to be configured to perform particular operations or actions means that the one or more programs include instructions that, when executed by digital and/or quantum data processing apparatus, cause the apparatus to perform the operations or actions. A quantum computer may receive instructions from a digital computer that, when executed by the quantum computing apparatus, cause the apparatus to perform the operations or actions.

Digital and/or quantum computers suitable for the execution of a digital and/or quantum computer program can be based on general or special purpose digital and/or quantum microprocessors or both, or any other kind of central digital and/or quantum processing unit. Generally, a central digital and/or quantum processing unit will receive instructions and digital and/or quantum data from a read-only memory, or a random access memory, or quantum systems suitable for transmitting quantum data, e.g. photons, or combinations thereof.

Some example elements of a digital and/or quantum computer are a central processing unit for performing or executing instructions and one or more memory devices for storing instructions and digital and/or quantum data. The central processing unit and the memory can be supplemented by, or incorporated in, special purpose logic circuitry or quantum simulators. Generally, a digital and/or quantum computer will also include, or be operatively coupled to receive digital and/or quantum data from or transfer digital and/or quantum data to, or both, one or more mass storage devices for storing digital and/or quantum data, e.g., magnetic, magneto-optical disks, or optical disks, or quantum systems suitable for storing quantum information. However, a digital and/or quantum computer need not have such devices.

Digital and/or quantum computer-readable media suitable for storing digital and/or quantum computer program instructions and digital and/or quantum data include all forms of non-volatile digital and/or quantum memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks; and quantum systems, e.g., trapped atoms or electrons. It is understood that quantum memories are devices that can store quantum data for a long time with high fidelity and efficiency, e.g., light-matter interfaces where light is used for transmission and matter for storing and preserving the quantum features of quantum data such as superposition or quantum coherence.

Control of the various systems described in this specification, or portions of them, can be implemented in a digital and/or quantum computer program product that includes instructions that are stored on one or more tangible, non-transitory machine-readable storage media, and that are executable on one or more digital and/or quantum processing devices. The systems described in this specification, or portions of them, can each be implemented as an apparatus, method, or electronic system that may include one or more digital and/or quantum processing devices and memory to store executable instructions to perform the operations described in this specification.

While this specification contains many specific implementation details, these should not be construed as limitations on the scope of what may be claimed, but rather as descriptions of features that may be specific to particular implementations. Certain features that are described in this specification in the context of separate implementations can also be implemented in combination in a single implementation. Conversely, various features that are described in the context of a single implementation can also be implemented in multiple implementations separately or in any suitable sub combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

What is claimed is:

1. A system for fabricating quantum hardware for use in a quantum computing system, the system comprising:
at least one metrology chamber operable to receive a workpiece, the workpiece comprising a quantum structure associated with the quantum hardware, the metrology chamber comprising at least one detector operable to characterize an atomic scale parameter associated with a surface of the quantum structure;
at least one process chamber operable to receive the workpiece, the at least one process chamber operable to perform a fabrication process on the quantum structure based at least in part on the atomic scale parameter; and
a transfer apparatus operable to transfer the workpiece between the at least one metrology chamber and the at least one process chamber without exposure to ambient.

2. The system of claim 1, wherein the transfer apparatus comprises a vacuum chamber.

3. The system of claim 1, wherein the transfer apparatus is operable to transfer the workpiece between the at least one metrology chamber and the at least one process chamber under vacuum pressure.

4. The system of claim 1, wherein the atomic scale parameter is associated with a detection limit of at least about 1×10¹⁴ atoms/cm³.

5. The system of claim 1, wherein the quantum structure is a portion of a superconducting qubit.

6. The system of claim 1, wherein the at least one detector comprises a mass spectrometer.

7. The system of claim 1, wherein the at least one detector comprises residual gas analyzer (RGA) detector.

8. The system of claim 1, wherein the at least one detector comprises a secondary-ion-mass-spectroscopy (SIMS) detector or an X-ray photoelectron spectroscopy (XPS) detector.

9. The system of claim 1, wherein the at least one detector is operable to perform thermal desorption spectroscopy (TDS) measurements.

10. The system of claim 1, wherein the at least one metrology chamber comprises a surface treatment chamber, wherein the at least one detector is an in-situ detector in the surface treatment chamber.

11. The system of claim 10, wherein the in-situ detector comprises an ellipsometer, an optical emission spectroscopy (OES) detector, or a residual gas analyzer (RGA) detector.

12. The system of claim 10, wherein the surface treatment chamber comprises a plasma-based source or an ion beam source.

13. The system of claim 1, wherein the at least one process chamber comprises a surface treatment chamber.

14. The system of claim 1, wherein the at least one process chamber comprises a deposition chamber.

15. A method for fabricating quantum hardware for use in a quantum computing system, the method comprising:
providing a workpiece to a metrology chamber, the workpiece comprising one or more surfaces associated with a quantum structure for the quantum hardware;
characterizing at least one atomic scale parameter associated with a surface of the quantum structure with at least one detector in the metrology chamber;
after characterizing the at least one atomic scale parameter, transferring the workpiece to a process chamber under vacuum pressure without exposure to ambient; and
performing at least one fabrication process on the surface of the quantum structure in the process chamber based at least in part on the atomic scale parameter.

16. The method of claim 15, wherein the atomic scale parameter is associated with a detection limit of at least about 1×10¹⁴ atoms/cm³.

17. The method of claim 15, wherein the metrology chamber is a surface treatment chamber having an in-situ detector.

18. The method of claim 15, wherein the method comprises transferring the workpiece to a surface treatment chamber and performing a surface treatment process prior to providing the workpiece to the metrology chamber.

19. A system for fabricating quantum hardware for use in a quantum computing system, the system comprising:
an outgas chamber operable to receive a workpiece having a quantum structure, the outgas chamber comprising a first detector operable to monitor one or more organic compounds using mass spectroscopy;
a materials characterization chamber, the materials characterization chamber having a second detector operable to detect an atomic scale parameter;
a thermal processing chamber, the thermal processing chamber comprising a third detector, the third detector comprising a thermal desorption spectroscopy (TDS) detector);
a surface treatment chamber, the surface treatment chamber comprising a plasma source or an ion beam source operable to perform a surface treatment process on the workpiece;
a deposition chamber; and
a transfer chamber coupled to the outgas chamber, the surface treatment chamber, the materials characterization chamber, the transfer chamber operable to transfer the workpiece between one or more of the outgas chamber, the materials characterization chamber, the thermal processing chamber, the surface treatment chamber, and the deposition chamber without exposure to ambient.

20. The system of claim 19, wherein the surface treatment chamber comprises an in-situ detector, the in-situ detector comprising one or more of an ellipsometer, an optical emission spectroscopy (OES) detector, or a residual gas analyzer (RGA) detector.
